(19) United States
(12) Patent Application Publication
(10) Pub. No.: US 2004/0177303 A1
(43) Pub. Date: Sep. 9, 2004

(54) Analog-hybrid ic test system

(76) Inventor: Toshiyuki Miura, Tokyo (JP)

Correspondence Address: GALLAGHER & LATHROP, A PROFESSIONAL CORPORATION, 601 CALIFORNIA ST, SUITE 1111, SAN FRANCISCO, CA, 94108, US

(21) Appl. No.: 10/470,667

(22) PCT Filed: Feb. 12, 2002
(86) PCT No.: PCT/JP02/01148

(30) Foreign Application Priority Data
Feb. 9, 2001 (JP) 2001-033953

(51) Int. Cl. G06F 11/00; G01R 31/28

(52) U.S. Cl. 714/741

(57) ABSTRACT

An analog-digital hybrid IC test system which is equipped with a logic test system and an analog test system and controls both of them by a main program, and in which the main program has a pattern generation program for a logic test and a description for generating a control signal for the analog test system is added to part of the pattern generation program.

### TECHNICAL FIELD

The present invention relates to an analog-digital hybrid IC test system for testing analog-digital hybrid ICs equipped with analog circuits and digital circuits (logic circuits).

### PRIOR ART

FIG. 3 is a diagrammatic showing of the configuration of a conventional analog-digital hybrid IC test system. The analog-digital hybrid IC test system comprises an analog test system 100 and a logic test system (a digital test system) 200, and these test systems 100 and 200 are placed under the control of a main controller 300 for testing operations of analog and digital circuits of a device under test DUT mounted on a performance board PB. PB denotes a performance board that supports the device under test DUT electrically and mechanically.

The analog test system 100 is composed principally of a high precision clock source 101, an event sequencer 102, a burst block generator 103, an event matrix 104, a clock matrix 105, analog waveform generators 106, and digitizers 107. A logic synchronous part 400 has an event sequencer 402 for generating a plurality of events synchronized with the logic test system 200 and a burst clock generator 403 for generating a plurality of burst clocks.

The analog waveform generators 106 and the digitizers 107 are provided corresponding in number to analog signal input pins and analog signal output pins of the device under test DUT, respectively. The analog waveform generators 106 each input an analog signal to the analog signal input pin connected thereto. Each analog waveform generator 106 responds to an event (a control command ) input thereto to start generation of a designated waveform, generating a waveform sample on each input thereto a clock and outputting it in analog form. The digitizers 107 each connected to one of the analog signal output pins responds to a given event to start inputting thereto an input waveform and, upon each application of an input clock, performs an analog-digital conversion of an output analog signal from the device under test DUT to a digital sample value. Waveform data on the AD-converted digital sample is input to a memory or the like not shown, in which it is compared with an expected value for evaluation on a pass/fail basis.

The event sequencer 102 starts/stops under the control of a main program to generate plural kinds of events, which are provided to all event selectors SEL in the event matrix 104. Further, in this prior art example plural events generated by the event sequencer 402 of the logic synchronous are also provided to all of the event selectors SEL so that they can be selected. Each event selector SEL selects any one event EV from among the input plural events under the control of the main controller 300 and provides it to the corresponding analog waveform generator 106.

The burst clock generator 103 extracts clocks CK of different periods and/or different numbers from a clock train provided from the clock source 101, for instance, and provides the extracted plural clocks to all clock selectors SEL in the clock matrix 105. Similarly, the burst clock generator 403 of the logic synchronous part 400 also provides plural kinds of clocks, generated in synchronization with pattern generation, to all clock selectors SEL in the clock matrix 105. Each clock selector SEL selects a designated one of the input plural clocks CK under the control of the main controller 300, and provides it to the analog waveform generator 106 and the digitizer 107 corresponding to the selector. Based on the event and clock input thereto, the digitizer 107 performs an analog-digital conversion of an input signal from the analog signal output pin to a sequence of digital sample values which terminates just at a predetermined position of the signal waveform, and terminates at the predetermined waveform position.

The logic test system 400 comprises, as depicted in FIG. 4, a pattern generator 201, a waveform formatter 202, a driver 203, an analog comparator 204, a logic comparator 205, and a failure analysis memory 206.

The pattern generator 201 generates digital pattern data which is provided to the device under test DUT. The waveform formatter 202 converts the pattern data from the pattern generator 201 to a pattern signal of a real waveform, and applies the pattern signal via the driver 203 to a digital input terminal of the device under test DUT

A response signal provided at a digital output terminal (which is usually used both as an input terminal and as an output terminal) is determined by the analog comparator 204 as to whether it is a logic signal having a normal L-logic voltage and a normal H-logic voltage, and if these comparison results are good, the response signal is compared by the logic comparator 205 with an expected value from the pattern generator 201; when noncoincidence is detected, it is determined that the device under test is malfunctioning. Incidentally, the failure analysis memory 206 is a memory which stores the pattern data output from the pattern generator 201 when the noncoincidence is detected by the logic comparator 205. By reading out the pattern data from the failure analysis memory 206 after the test, malfunctions of the digital circuit of the device under test DUT are analyzed.

The main controller 300 (FIG. 3) has loaded therein a main program 301. In the main program 301 there is described, for example, a start/stop instruction 302 for the event sequencer 102 or a patter generation program. The execution of the start/stop instruction 302 for the event sequencer 102 applies a start control signal ST or stop control signal STP to the event sequencer 102 to start or stop it. When the event sequencer 102 is active, plural events are read out from an event memory (not shown, in particular) mounted in the event sequencer 102, and these events are provided to all the event selectors SEL in the event matrix 104, and each event selector SEL is controlled by the control part 300 to select and output any one of the events EV, or not to select and output any of the events.

The analog waveform generators 106 are each set by the event sent from the event sequencer 102 for starting waveform generation and waveform switching, thereby setting an analog waveform to be applied to the device under test DUT. The digitizers 107 are each put in the analog-digital conversion mode, in which its timing for starting and stopping the analog-digital conversion of the input signal from the device under test DUT is controlled.

The test operation of the logic test system 200 is performed by executing the pattern generation program 303 described in the main program 301 to cause the pattern generator 201 in the logic test system to generate the test pattern signal.

Incidentally, in some devices under test DUT analog and digital circuits operate in synchronization with each other. To test this kind of devices, it is conventional to provide the logic synchronous part having the event sequencer 402 and the burst clock generator 403. The events and the clocks generated by the event sequencer 402 and the burst clock generator 403, respectively, are provided to the event matrix 104 and the clock matrix 105 so that they can be selected; by this, the analog test system 100 is made operable in synchronization with the logic test system 200.

As described above, the logic synchronous part 400 is used for operating the logic test system 200 and the analog test system 100 in synchronization with each other, but its startup it is necessary to put in motion the event sequencer 102 or burst clock generator 103 in synchronization with the logic test system 200.

Since the operation of the analog test system 100 is placed under the control of the main program of the main controller 300, the event sequencer 102 and the burst clock generator 103 can only be started up in the prior art by the start/stop instruction 302 described in the main program 301 or an external signal, for example, a startup signal EXT from the performance board PB.

Even if the event sequencer 102 or burst clock generator 103 is started up by the start/stop instruction 302 described in the main program 301, it is difficult to achieve synchronization between operations of the logic test system 200 and the analog test system 100 because the logic test system 200 operates in accordance with the description of the pattern generation program 303.

### DISCLOSURE OF THE INVENTION

An object of he present invention is to provide an analog-digital hybrid IC test system configured to facilitate synchronization between the start/stop operation of the analog test system and the start/stop operation of the logic test system.

The analog-digital hybrid IC test system according to the present invention comprises a test system which has a logic test system and an analog test system and controls them by a main program, the main program having a pattern generation program and a description of a control instruction for generating an analog test system control signal being added to part of the pattern generation program.

In the above-mentioned test system there is provided start/stop control signal generating means which converts said analog test system control instruction read out of said pattern generation program into a start/stop control signal for application to said analog test system.

With the constitution of the present invention, it is possible to time the execution of the analog test system start/stop command with the pattern generation timing since the start/stop control instructions for the event sequencer and the burst clock generator are described in part of the pattern generation program.

This offers an advantage of achieving highly accurate synchronization between the operation timing of the analog test system and the operation timing of the logic test system. Moreover, since the program of the analog test system can be managed on the program of the logic test system, it is also possible to debug the program with ease.

### BRIEF DESCRIPTION OF THE DRAWINGS

FIG. 1 is a block diagram illustrating an embodiment of the analog-digital hybrid IC test system.

FIG. 2 is a diagram for explaining the operation of the FIG. 1 embodiment.

FIG. 3 is a block diagram explanatory of the prior art.

FIG. 4 is a block diagram for explaining the configuration of a logic test system in FIG. 3

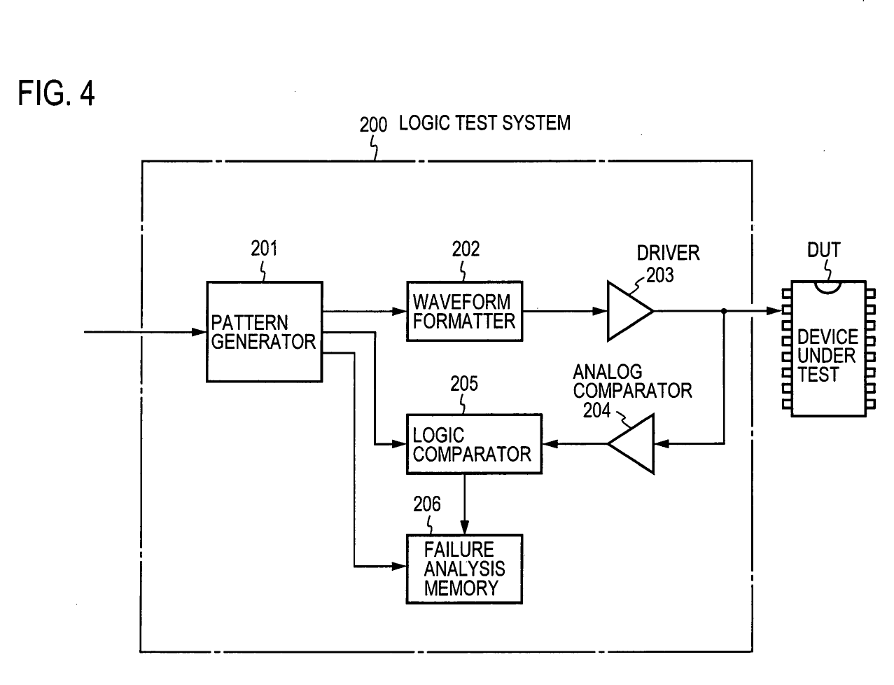

### BEST MODE FOR CARRYING OUT THE INVENTION

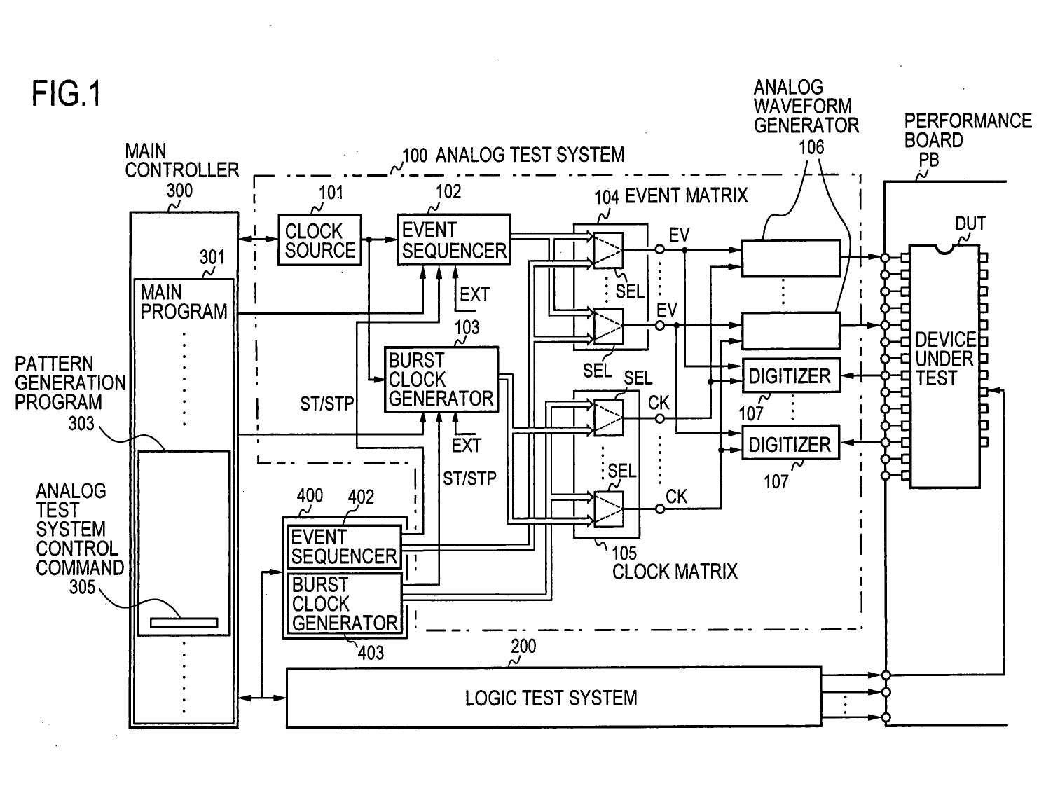

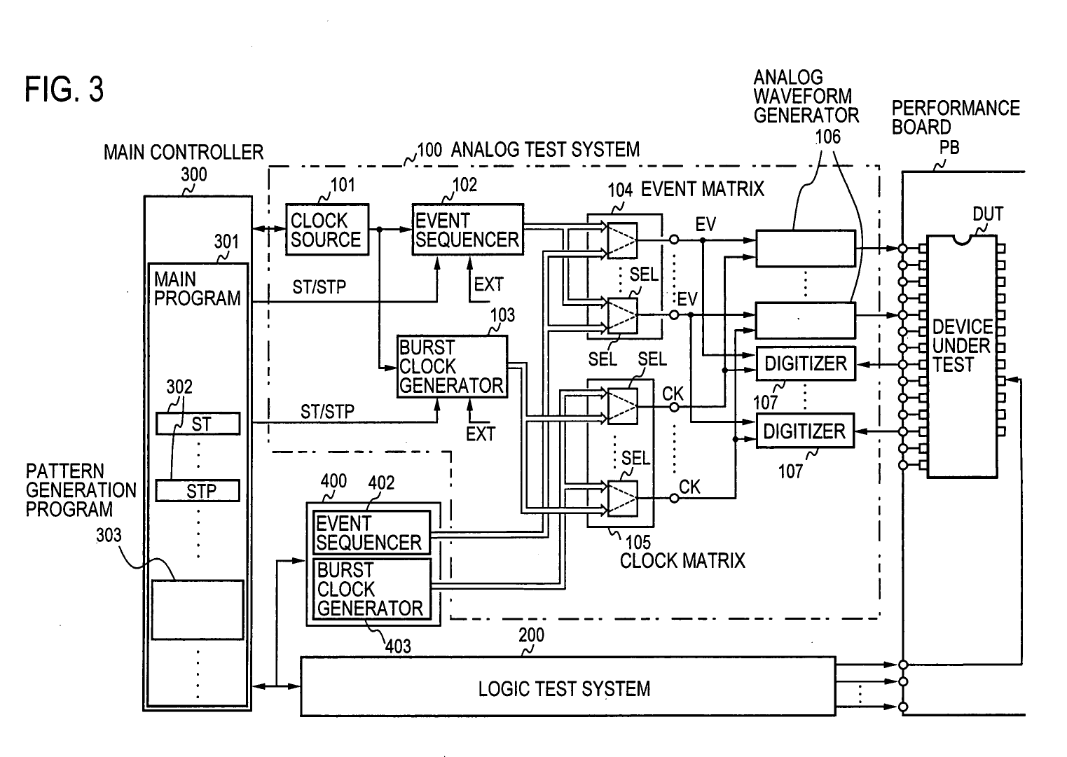

FIG. 1 illustrates an embodiment of the analog-digital hybrid IC test system according to the present invention. In FIG. 1, the parts corresponding to those in FIG. 3 are identified by the same reference numerals and no explanation will be given of the same configuration and operation as those in the prior art example.

The configuration characteristic of the present invention resides in that a control instruction 305 for the analog test system 100 is described in part of the pattern generation program 303 described in the main program 301 installed in the main controller 303.

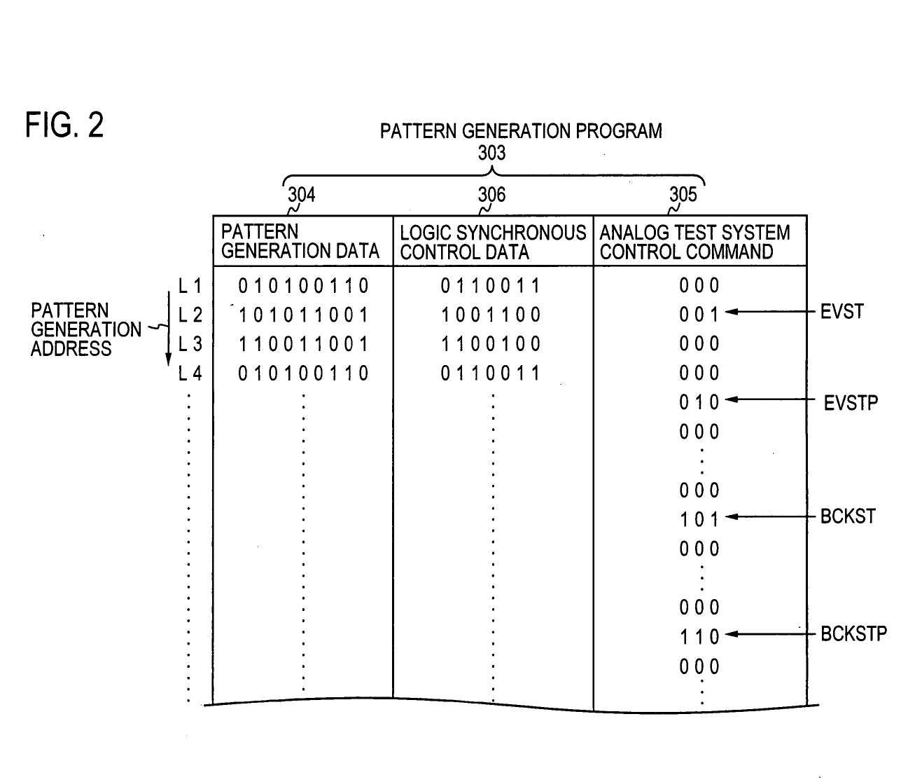

In Fig.2 there is depicted, by way of example, the description of the pattern generation program 303 and the control instruction for the analog test system 100. Pattern generation data 304 is described at each of pattern generation addresses L1, L2, L3, . . . , where logic synchronous control data 306 and the control instruction 305 for the analog test system are also described. In the control instruction 305 for the analog test system, for example, as depicted in FIG. 2, an event sequencer start instruction EVST, an event sequencer stop instruction EVSTP, a burst clock generator start instruction BCKST and a burst clock generator stop instruction BCKSTP are written at desired timing (i.e., addresses) for the pattern generation by the pattern generation data 304.

Since the execution of such a pattern generation program 303 generates a start/stop control instruction ST/STP for the analog test system in synchronization with, for example, the rise-up timing of a test pattern signal, it is possible to effect start/stop control of the event sequencer 102 and the burst clock generator 103 in synchronization with arbitrary timing for the rise or fall of the test pattern signal for the logic test system 200.

In the FIG. 2 example, the control instruction for the analog test system is composed of three bits. In the illustrated example, “0, 0, 1” of the three-bit control instruction is defined as the start instruction EVST for the event sequencer 102, “0, 1, 0” as the stop instruction EVSTP therefor, “1, 0, 1” as the start instruction BCKST for the burst clock generator 103 and “1, 1, 0” as the stop instruction BCKSTP therefor.

The control instructions, which are read out as the pattern generation program 303 is executed, are fed, in this embodiment, to the logic synchronous part 400, wherein they are provided to the event sequencer 402 and the burst clock generator 403 to generate therein start/stop instructions ST/STP, which are provided to the event sequencer 102 and the burst clock generator1O3. Accordingly, it is possible to control the start and stop of the event sequencer 102 and the burst clock generator 103 in synchronization with pattern generation.

In this embodiment the event sequencer 402 and the burst clock generator 403 of the logic synchronous part 400 have been described to be used also as means for generating the start/stop control signals ST/STP in response to the control instructions EVST, EVSTP and BCST, BCSTP, respectively. That is, the logic synchronous part 400 is shown to be used as means for generating the control signals in response to the control instructions, but it is a matter of course that such means for generating the control signals in response to the control instructions can be provided separately of the logic synchronous part 400.

### EFFECT OF THE INVENTION

As described above, since the present invention is configured to describe start/stop instructions for the analog test system 100 in the pattern generation program 303 of the logic test system 200, the analog test system 100 can be controlled to operate in synchronization with the pattern generating operation. This offers an advantage of ensuring accurate testing of semiconductor devices which are required to operate analog and digital systems in synchronization with each other. Moreover, since the pattern generation program and the analog test system start/stop instructions are written along with each other, it is also possible to offer an advantage that facilitate debugging of programs; hence, the invention is of great utility when used in practice.

1. An analog-digital hybrid IC test system which is equipped with a logic test system and an analog test system and controls both of them by a main program, characterized in that:
said main program includes a pattern generation program; and control instructions for generating control signals for said analog system are described in part of said pattern generation program.

2. The analog-digital hybrid IC test system claimed in claim 1, which has start/stop control signal generating means for converting said analog system control instructions read out of said pattern generation program to start/stop control signals for application to said analog test system.

3. The analog-digital hybrid IC test system as claimed in claim 2, wherein said analog test system includes:
an event sequencer and a burst clock generator both controlled by said main program to generate plural kinds of event and plural kinds of clocks, respectively;
an event matrix having a plurality of event selectors each of which selects and outputs any one of said plural kinds of events;
a clock matrix having a plurality of clock selectors each of which selects and outputs any one of said plural kinds of clocks;
analog waveform generators each provided in correspondence to said each event selector and said each clock selector, for generating a waveform at specified timing in response to an event from said each event selector and a clock from said each clock selector and for applying said waveform to the corresponding input analog pin of an IC under test;
digitizers each responsive to an event from said each event selector and a clock from said each clock selector to perform specified sampling of an input analog signal at specified timing for conversion to a digital signal; and
logic synchronous means for applying control signal generated by said pattern generation program for said logic test system to said event sequencer and said burst clock generator to control their start and stop.

4. The analog-digital hybrid IC test system as claimed in claim 3, characterized in that control instructions for said analog test system described in part of said pattern generation program are start/stop control instructions for said event sequencer.

5. The analog-digital hybrid IC test system as claimed in claim 3, characterized in that control signals for said analog test system described in part of said pattern generation program are start/stop control instructions for said burst clock generator.
